(19) United States
(12) Patent Application Publication
(10) Pub. No.: US 2006/0216924 A1
(43) Pub. Date: Sep. 28, 2006

(54) BEOL integration scheme for etching damage free ELK

(76) Inventors: Zhen-Cheng Wu, Hsinchu (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(21) Appl. No.: 11/091,307

(22) Filed: Mar. 28, 2005

(51) Int. Cl. H01L 21/4763

(52) U.S. Cl. 438/623; 438/619; 438/622

(57) ABSTRACT

A preferred embodiment of the invention provides a semiconductor device fabrication method comprising forming a set of interlevel wiring interconnect structures through a low-k dielectric layer, wherein the set comprises a lower wiring level, an upper wiring level, and a conductive via connecting the lower wiring level and the upper wiring level. The method further comprises anisotropically etching the first dielectric layer using the upper wiring level as a mask such that substantially all the first dielectric layer is removed except for a residual dielectric underneath the upper wiring level. A preferred embodiment further comprises removing the residual dielectric with an isotropic etch and then filling substantially all space between adjacent interlevel wiring interconnect structures with a ELK dielectric layer. An alternative embodiment provides a method for forming a dual damascene interconnect structure in an ELK dielectric.

### TECHNICAL FIELD

This invention relates generally to semiconductor device fabrication and more particularly to a method for forming low-k dielectric layers.

### BACKGROUND

An important objective in the advancement of integrated circuit (IC) technology is the reduction of IC dimensions. Such reduction of IC dimensions reduces area capacitance and is critical to increasing the performance of integrated circuits. Moreover, reducing the area of an IC die leads to higher yield in IC fabrication. Such advantages are among the driving forces to constantly scale down IC dimensions.

As the density of semiconductor devices increases, however, the resistance capacitance (RC) delay time increasingly dominates the circuit performance. To reduce the RC delay, there is a desire to switch from conventional dielectrics to low-k dielectrics, which have a dielectric constant less than SiO₂, or about 4. Low-k dielectrics may also include a class of low-k dielectrics frequently called extreme low-k (ELK) dielectrics, which have a dielectric constant less than about 2.5. Low-k materials are particularly useful as intermetal dielectrics (IMDs) and as interlayer dielectrics (ILDs). Despite their advantages, low-k materials raise many problems relating to their integration into conventional processing methods.

One process integration issue of particular concern is in the formation of conductive interconnect structures, such as in the damascene process. The damascene process typically includes etching with a high-energy plasma. The low-k materials are susceptible to damage from a plasma etch because they are softer, less chemically stable, or more porous, or any combination of these factors. The plasma damage manifests itself in higher leakage currents, lower breakdown voltages, and changes in the dielectric constant associated with the low-k dielectric material. Some damaged low-k dielectrics are easily deformed during exposure to wet chemical cleanups, which results in the loss of critical dimension (CD) structures.

In view of these and other process integration problems facing low-k dielectrics, there is a need for new semiconductor methods and structures.

### SUMMARY OF THE INVENTION

These and other problems are generally solved or circumvented, and technical advantages are generally achieved, by preferred embodiments of the present invention, which comprises a method for the integration of low-k and ELK dielectric layers into semiconductor interconnect and other fabrication processes.

A preferred embodiment provides a semiconductor device fabrication method comprising forming a set of interlevel wiring interconnect structures through a first dielectric layer. Preferably, the set comprises a lower wiring level, an upper wiring level, and a conductive via connecting the lower wiring level and the upper wiring level. A preferred embodiment further comprises anisotropically etching the first dielectric layer using the upper wiring level as a mask. Preferably, substantially all the first dielectric layer is removed except for a residual dielectric underneath the upper wiring level. The preferred embodiment further comprises removing the residual dielectric with an isotropic etch and filling substantially all space between adjacent interlevel wiring interconnect structures with a second dielectric layer.

In a preferred embodiment of the invention, the first dielectric layer comprises a material having a dielectric constant greater than about 2.5, and the second dielectric layer comprises a material having a dielectric constant less than about 2.5. In another preferred embodiment, the first dielectric layer comprises a low-k dielectric, and the second dielectric layer comprises an ELK dielectric.

An alternative embodiment of the invention provides a method for forming an interconnect structure. An embodiment comprises forming a first dielectric layer on a substrate and forming a dual damascene structure through the first dielectric layer to the substrate. Preferably, the dual damascene structure comprises a trench, wherein the trench overlies a via and at least a portion of the first dielectric layer. Embodiments further comprise forming a first and second recess. Forming the first recess includes anisotropically etching the first dielectric layer using the trench as a mask. Forming the second recess is performed by isotropically etching a portion of the first dielectric layer underlying the trench. Preferred embodiments include forming a second dielectric layer by filling the first recess and the second recess with a second dielectric.

Yet another embodiment provides a method for fabricating a semiconductor device having an extreme low-k dielectric (ELK). The method comprises removing substantially all of a first dielectric from between adjacent interconnects using an anisotropic etch and then using an isotropic etch. Preferably, using an anisotropic etch comprises using an interconnect as a mask and filling substantially all of a space between adjacent interconnects with an ELK. In a preferred embodiment of the invention, the space between adjacent interconnects comprises a recessed area under a dual damascene trench.

Additional features and advantages of embodiments of the invention will be described hereinafter, which form the subject of the claims of the invention. It should be appreciated by those skilled in the art that the specific embodiments disclosed might be readily utilized as a basis for modifying or designing other structures or processes for carrying out the purposes of the present invention. It should also be realized by those skilled in the art that such equivalent constructions and variations on the example embodiments described do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a semiconductor device at an intermediate step in an exemplary damascene process according to preferred embodiments;

FIG. 2 is cross-sectional view showing an intermediate semiconductor device that includes a set of interconnects and a low-k dielectric according to preferred embodiments;

FIG. 3 is cross-sectional view showing an anisotropic etch of the low-k dielectric of FIG. 2 according to preferred embodiments;

FIG. 4 is a cross-sectional view comparing preferred embodiments of FIG. 3 with a conventional ELK dielectric process;

FIG. 5 is cross-sectional view showing an isotropic etch of the intermediate device of FIG. 3 prior to ELK dielectric fabrication according to preferred embodiments; and

FIG. 6 is cross-sectional view showing ELK dielectric formation according to preferred embodiments.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The operation and fabrication of the presently preferred embodiments are discussed in detail below. However, the embodiments and examples described herein are not the only applications or uses contemplated for the invention. The specific embodiments discussed are merely illustrative of specific ways to make and use the invention, and do not limit the scope of the invention or the appended claims.

This invention relates generally to semiconductor device fabrication and more specifically to low-k and ELK dielectric formation. The present invention will now be described with respect to preferred embodiments in a specific context, namely the creation of an ELK dielectric and copper conductive lines in the damascene process. It is believed that embodiments of this invention are particularly advantageous in the damascene interconnect process. A significant advantage of embodiments is the ease at which they are integrated into back end of line (BEOL) processing applications. It is further believed that embodiments described herein will benefit other integrated circuit applications wherein dielectric processing damage and dielectric formation are a concern. Therefore, the specific embodiments discussed are merely illustrative of specific ways to make and use the invention, and do not limit the scope of the invention.

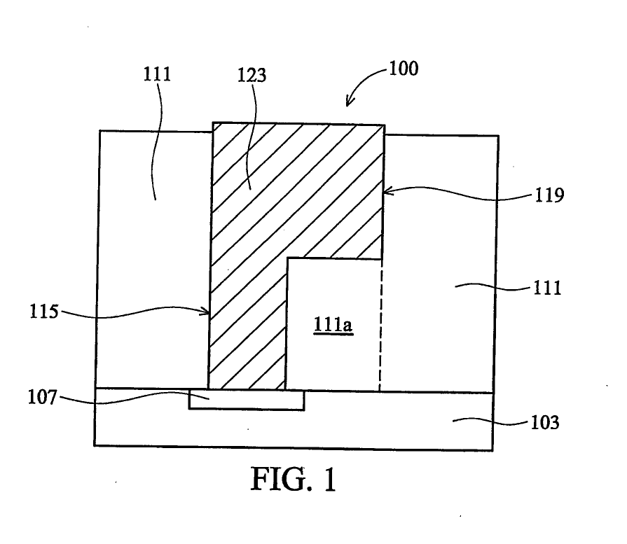

Referring now to FIG. 1, there is shown a cross section of a device 100 at an intermediate semiconductor fabrication stage. Included in device 100 is substrate 103, which may comprise silicon, silicon on insulator (SOI), Ge, SiC, GaAs, GaAlAs, InP, GaN SiGe. The substrate 103 may further comprise a conductive feature such as functional and logical devices, a FET (or a component thereof such as a source, a drain region, or an electrode gate), conductors, levels of wiring, other interconnected layers, active or passive devices, or combinations thereof. For the purpose of describing embodiments of the invention below, the substrate 103 comprises a dielectric such as an ILD and a conductive interconnect 107. Further illustrated in FIG. 1 is a dielectric layer 111 on the substrate 103. Formed through the dielectric layer 111 is an opening such as a via 115, which contacts the conductive interconnect 107. Overlying the via 115 and at least a portion of the dielectric layer 111 is a second opening or a trench 119. The via 115 and the trench 119 may together be referred to as a damascene interconnect structure or a dual damascene interconnect structure. A conductor 123 fills the via 115 and the trench 119. Typically, the dielectric layer 111 is between about 3000 to 6000 Angstroms thick.

One skilled in the art recognizes that many conventional damascene features such as barrier layers, adhesion layers, etch stop layers, etc., are not illustrated in FIG. 1. While such features are preferred in the damascene process, their illustration is not necessary for understanding this invention. Therefore, they are omitted from illustrations of preferred embodiments for clarity.

As illustrated in FIG. 1, the trench 119 overlies a small portion of the dielectric layer 111. This portion is illustrated by the recessed area under the dual damascene trench, which is demarcated by the dashed line in FIG. 1. The recessed dielectric 111a, or the portion of the dielectric layer 111 that underlies the trench 119 overhang, is a particularly preferred feature. As will be described in more detail below, this feature permits the trench 119 to act as a patterning mask, thereby avoiding certain contamination problems associated with photoresist contamination.

Note that although the term layer is used throughout the specification and in the claims, the resulting features formed using the layer should not be interpreted together as only a continuous or uninterrupted feature. As will be clear from reading the specification, the layer may be separated into distinct and isolated features (e.g., active regions), some or all of which comprise portions of the layer. A layer may contain a plurality of materials deposited in separate steps.

FIG. 1 provides a convenient starting point for describing preferred embodiments of the invention. Briefly, preferred embodiments include forming an interconnect structure, such as that shown in FIG. 1, wherein the dielectric layer 111 comprises a low-k dielectric. Preferred embodiments further comprise replacing the low-k dielectric with an ELK dielectric, or more generally, replacing a first dielectric with a second dielectric. The replacing process is described in more detail below in relation to preferred embodiments.

As noted above, the first dielectric is preferably a low-k dielectric. In the illustration of preferred embodiments below, the description low-k is reserved for that group of low-k dielectrics having a dielectric constant greater than about 2.5.

The forming or depositing of the low-k dielectric may use several conventional methods including curing using a radio frequency (RF) plasma curing process. The low-k dielectric may be spun or CVD deposited using oxidation of an organosilicon compound containing C—H bonds and C—Si bonds. A suitable organosilicon compound includes the methyl-silane group, and oxidation may include an O₂ or CO₂ treatment with no post-treatment thermal curing required. Preferably, a low temperature curing is used, such as below 300° C., and more preferably below 50° C. at a power level of about 2000 W. In addition to setting the energy level, the power of the curing process is actively controlled by varying the curing time.

Suitable low-k dielectrics include a carbon-doped silicon dioxide, also referred to as organo silicate glass (OSG) and C-oxide. Preferred organic low-k materials include polyarylene ether, hydrogen silesquioxane (HSQ), methyl silsesquioxane (MSQ), polysilsequioxane, polyimide, benzocyclbbutene, and amorphous polytetrafluoroethylene (PTFE). Other types of low-k materials suitably used with the method of the present invention include fluorinated silicate glass (FSG) such as fluorine-doped oxide-.

As noted above, the second dielectric is preferably an ELK dielectric wherein the dielectric constant is less than about 2.5. Suitable ELK dielectrics include porous dielectrics, including porous combinations of C-doped oxide and spun-on-glass (SOG). For wide line features (greater than about 0.5 μm), the ELK coating may include a spun-on layer followed by a CVD layer to prevent cracking. Other, ELK dielectrics include a class of dielectrics that contain an unreacted, pore-generating material, or porogen. Heating the porogen above its decomposition temperature generates pores in the dielectric. ELK dielectrics may be deposited by oxidation of an organosilicon compound using PECVD at about 150 to 250° C.

By way of example, Dow Chemical's porous SILK product and JSR Corporation's JSR 5109 are suitable, commercially available low-k precursors that utilize an organic host material. In preferred embodiments, the low-k dielectric comprises Shipley's commercially available ZIRKON™ LK ILD. ZIRKON™ LK ILD is a blend of a methylsilsesquioxane (MSQ) based material with acrylic, polymer-based, nano-particle porogen dispersed in a solvent (PGMEA). An alternative preferred ELK includes PECVD Si_{w}OₓC_{y}H_{z} because it has the potential to achieve k<2 either with or without a porogen. CVD deposition is preferred with wide lines because of the better adhesion, less susceptibility to cracking, better planarity, and better mechanical strength exhibited by CVD films and layers.

ZIRKON™ LK ILD is preferably deposited using a conventional spin coater. After depositing, it is partially cured, preferably in a vertical furnace between about 250 and 300° C. in order to cross-link the matrix. Degradation of the ZIRKON™ LK ILD porogen begins at about 275° C., and complete degradation occurs at about 450° C.

ELK dielectric curing may include a remote plasma process that does not directly bombard the deposited material and does not prevent or negatively affect the desired chemical reactions from happening. The curing may be performed in Rapid Thermal Processing (RTP) equipment with a radiation source. The curing process may last between approximately one to ten minutes and may occur at a temperature of approximately 250° C. to 450° C. Embodiments may also include e-beam or UV curing.

Other, less preferred embodiments of the invention, may include replacing a first dielectric, which is non low-k, with a second dielectric, which is not an ELK, wherein the dielectric constant of the second dielectric is not equal to the dielectric constant of the first dielectric.

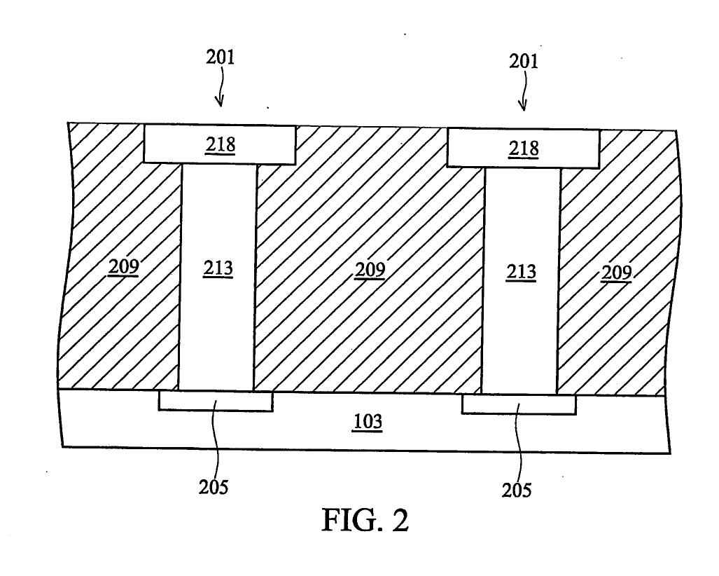

Turning now to FIG. 2, there is illustrated a cross-sectional view of a device at an intermediate fabrication stage according to preferred embodiments of the invention. FIG. 2 incorporates the preferred elements of FIG. 1, but FIG. 2 further includes a pair of interconnect structures 201 to more clearly illustrate preferred embodiments. The device in FIG. 2 comprises a substrate 103 that includes a conductor 205. The conductor 205 may comprise a lower wiring level, for example. Formed over the substrate is a low-k dielectric layer 209 having a dielectric constant greater than about 2.5. Formed through the low-k dielectric layer 209 is a set of interconnect structures 201. Each interconnect structure comprises a via 213 and a trench 218. The via 213 connects the trench 218 to the substrate conductor 205.

In alternative preferred embodiments, the trench 218 may be symmetrically placed over the via 213 as in FIG. 2, or asymmetrically placed as in FIG. 1. In preferred embodiments the trench 218 and the via 213 are filled with a conductor. The conductor within the trench 218, the conductor within the via 213, and the substrate conductor 205 may independently comprise Cu, Al, Au, Ag, W, Si, and combinations thereof including alloys.

In still other embodiments the interconnect structures 201 of FIG. 2 comprise a lower wiring level (e.g. 205) connected to an upper wiring level (e.g. 218) by a conductive via 213. The wiring levels may occupy adjacent levels or be separated by multiple dielectric levels.

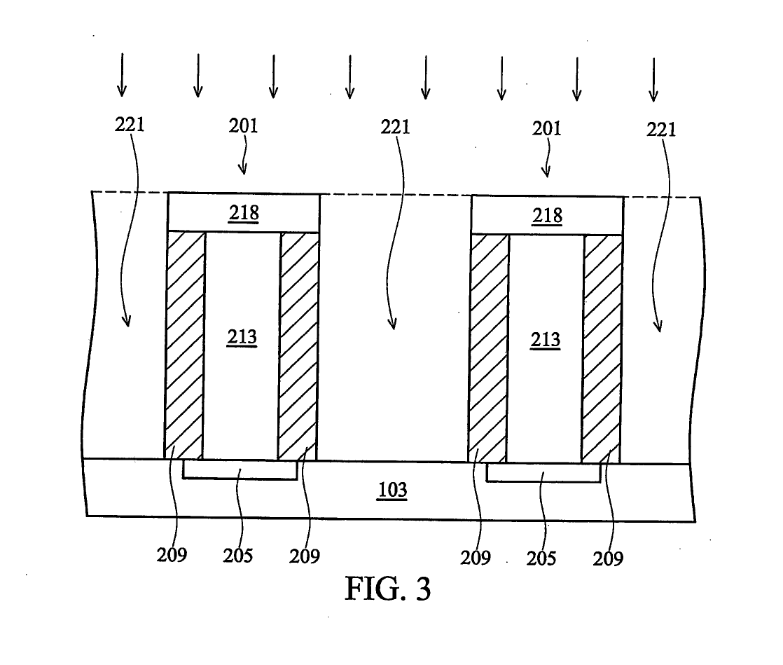

Turning now to FIG. 3, there is illustrated the device of FIG. 2 after further processing as described below. An anisotropic etch, such as a reactive ion etch (RIE) that includes C, F, nitrogen, and oxygen, is used to remove a portion of the low-k dielectric 209 between adjacent interconnect structures 201 thereby forming an opening or a recess 221 in a surface of the low-k dielectric 209. Preferably, the recess 221 runs completely through the low-k dielectric 209 to the substrate 103. As shown in FIG. 3, the anisotropic etch uses the trench 218 as a mask to the recess 221 through the low-k dielectric 209 down to the substrate 103.

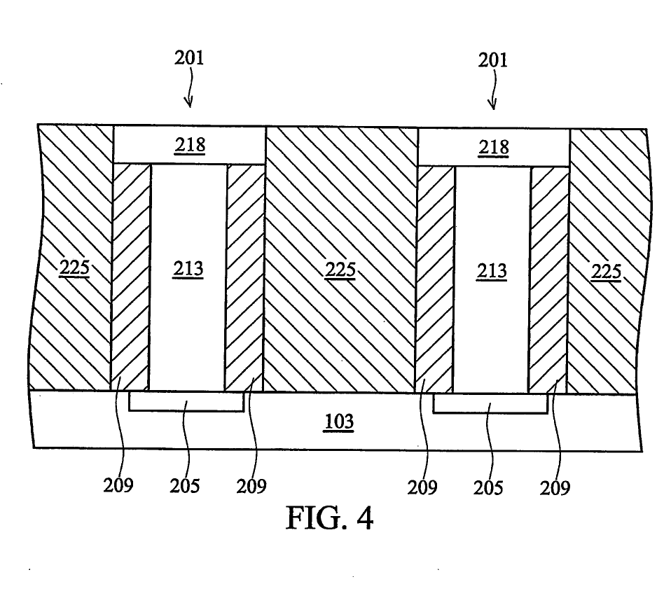

FIG. 4 compares the embodiments described above with a conventional ELK process integration scheme. In some conventional ELK fabrication methods, openings through the low-k dielectric 209, such as recess 221 (FIG. 3) are then filled with an ELK dielectric 225. This results in a combination of dielectrics as shown in FIG. 4. That is, in some regions, adjacent interconnect structures 201 are separated only with an ELK dielectric 225. In other regions, they are separated with both a low-k 209 and ELK 225 dielectric. In many situations, this is desirable because low-k dielectrics may have superior mechanical or chemical properties compared with ELK dielectrics. Superior properties may include higher density, resistance to deformation, more tolerance to harsh processing chemicals, and more of a barrier to chemical diffusion. Therefore, in some situations a dielectric residue, such as the low-k dielectric 209 remaining in FIG. 4 may be desirable. For example, it may help avoid distortion of the interconnect structure 201, or it may prevent diffusion from the via 213 to the ELK dielectric 225. However, in other situations, a dielectric residue left within a recess after an anisotropic etch creates problems.

As described above, plasma processing damages low-k dielectric layers. One such consequence of this is that an interface between the low-k dielectric 209 and the ELK dielectric 225 may be extremely rough. This is known to unacceptably increase RC delay in finished devices. Therefore, preferred embodiments include a second etching step to remove any dielectric residue left behind in the recess.

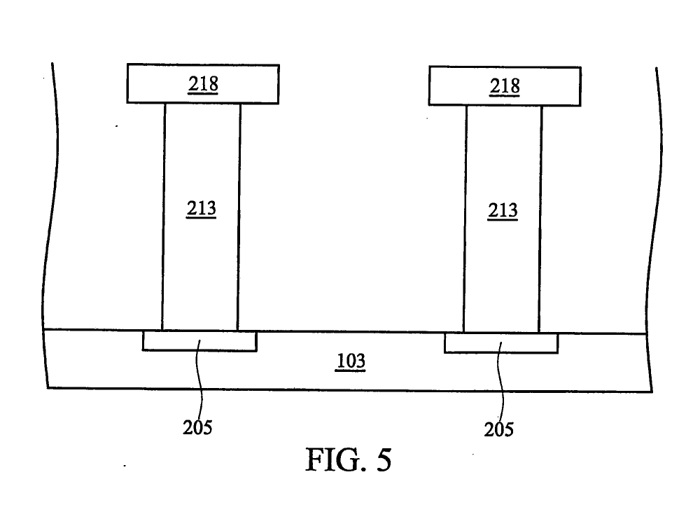

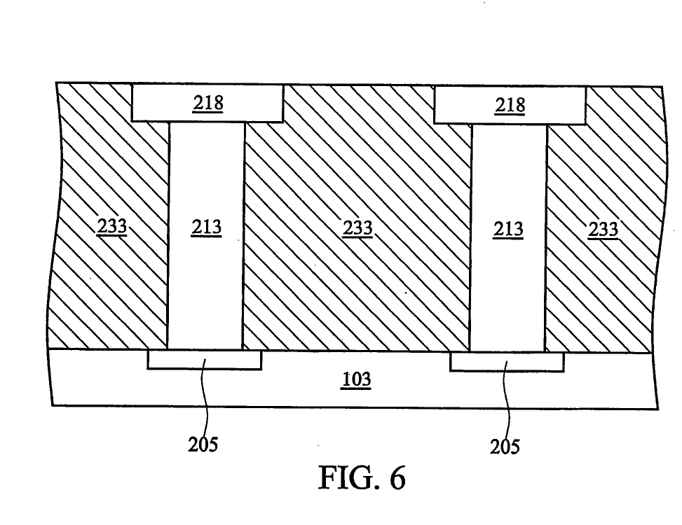

Turning now to FIG. 5, there is shown the structure of FIG. 3 after processing according to preferred embodiments. Specifically, the low-k dielectric 209 left behind by the anisotropic etch is removed, preferably using an isotropic etch, such as a conventional HF wet etch. This results in the intermediate device illustrated in FIG. 5. In other words, one embodiment comprises forming a first recess by anisotropically etching the first dielectric layer using the trench as a mask. A further embodiment comprises forming a second recess by isotropically etching a portion of the first dielectric layer underlying the trench, as illustrated in FIG. 5, and forming a second dielectric layer by filling the first recess and the second recess with a second dielectric, as illustrated in FIG. 6.

After the isotropic etching, substantially all the space between adjacent interconnect structures is filled with an ELK dielectric 233 and planarized by CMP as shown in FIG. 6. Thereafter, conventional processing methods may complete device fabrication. For example, a 500 Å SiCO etch stop layer (ESL) may be deposited using PECVD on the structure illustrated in FIG. 6.

Embodiments of the invention provide many advantages in the fabrication of devices having low-k and ELK dielectrics. For example, there is no etch/ash/wet strip damage to a porous ELK at a trench sidewall; therefore, a lower k value results. There is no Cu diffusion into porous ELK dielectrics caused by harsh barrier/seed deposition. It is easier to control pore size and porosity within ELK dielectrics. Embodiments are compatible with BEOL dual damascene fabrication schemes. Also, there is no additional tooling as embodiments are easily integrated into existing CVD and CMP processes, and the etching processes used are easy to control. Existing ELK deposition techniques are able to fill narrow features (i.e., aspect ratio greater than about 4). Also included in the list of advantages of preferred embodiments are reduced RC delay and reduced parasitic capacitance.

The embodiments of the invention described above are exemplary and not limiting. Variations apparent to those skilled in the art that include the features of the invention are within the scope of the invention and the appended claims. Although embodiments of the present invention and their advantages have been described in detail, it should be understood that various changes, substitutions and alterations can be made herein without departing from the spirit and scope of the invention as defined by the appended claims.

For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for fabricating a semiconductor device having an extreme low-k dielectric (ELK), the method comprising:
removing substantially all of a first dielectric from between adjacent interconnects using an anisotropic etch and then using an isotropic etch, wherein the using an anisotropic etch comprises using an interconnect as a mask; and
filling substantially all of a space between adjacent interconnects with the ELK.

2. The method of claim 1, wherein the space between the adjacent interconnects comprises a recessed area under a dual damascene trench.

3. The method of claim 1, wherein the mask comprises a dual damascene trench.

4. The method of claim 1, wherein the first dielectric comprises a low-k dielectric.

5. A semiconductor device fabrication method comprising:
forming a set of interlevel wiring interconnect structures through a first dielectric layer, wherein the set comprises a conductive feature, an upper wiring level over the conductive feature, and a conductive via connecting the conductive feature and the upper wiring level;
anisotropically etching the first dielectric layer using the upper wiring level as a mask such that substantially all the first dielectric layer is removed except for a residual dielectric underneath the upper wiring level;
removing the residual dielectric with an isotropic etch; and
filling substantially all space between adjacent interlevel wiring interconnect structures with a second dielectric layer.

6. The method of claim 5, wherein the first dielectric layer comprises a material having a dielectric constant greater than about 2.5.

7. The method of claim 5, wherein the first dielectric layer comprises a low-k dielectric.

8. The method of claim 5, wherein the second dielectric layer comprises a material having a dielectric constant less than about 2.5.

9. The method of claim 5, wherein the second dielectric layer comprises an ELK dielectric.

10. The method of claim 5, wherein the first dielectric layer comprises a material selected from the group consisting essentially of organo silicate glass (OSG), polyarylene ether, hydrogen silesquioxane (HSQ), methyl silsesquioxane (MSQ), polysilsequioxane, polyimide, benzocyclbbutene, PTFE, fluorinated silicate glass (FSG), and combinations thereof.

11. The method of claim 5, wherein the second dielectric layer comprises a material selected from the group consisting essentially of a porous dielectric, spun-on-glass (SOG), and combinations thereof.

12. The method of claim 5, wherein the anisotropic etch comprises a reactive ion etch (RIE).

13. The method of claim 5, wherein the isotropic etch comprises a HF wet etch.

14. The method of claim 5, wherein the set of interlevel wiring interconnect structures further comprise a material selected from the group consisting essentially of Cu, Al, Au, Ag, W, Si, and combinations thereof.

15. The method of claim 5, wherein the set of interlevel wiring interconnect structures further comprise a dual damascene interconnect structure.

16. The method of claim 5, wherein the filling substantially all space between adjacent interlevel wiring interconnect structures with a second dielectric layer comprises spin coating.

17. The method of claim 5, wherein the filling substantially all space between adjacent interlevel wiring interconnect structures with a second dielectric layer comprises spin coating and chemical vapor deposition.

18. A method for forming an interconnect structure comprising:
forming a first dielectric layer on a substrate;
forming a dual damascene structure through the first dielectric layer to the substrate, wherein the dual damascene structure comprises a trench, wherein the trench overlies a via and at least a portion of the first dielectric layer;
forming a first recess by anisotropically etching the first dielectric layer using the trench as a mask;
forming a second recess by isotropically etching a portion of the first dielectric layer underlying the trench; and
forming a second dielectric layer by filling the first recess and the second recess with a second dielectric.

19. The method of claim 18, wherein the first dielectric layer comprises a low-k dielectric.

20. The method of claim 18, wherein the second dielectric layer comprises an ELK dielectric.

21. The method of claim 18, wherein the forming a first recess by anisotropically etching further comprises a reactive ion etch (RIE).

22. The method of claim 18, wherein the forming a second recess by isotropically etching further comprises a HF wet etch.

23. The method of claim 18, wherein the forming a second dielectric layer further comprises spin coating.

24. The method of claim 18, wherein the forming a second dielectric layer further comprises spin coating and chemical vapor deposition.
